(19) United States
(12) Patent Application Publication
(10) Pub. No.: US 2013/0213475 A1
(43) Pub. Date: Aug. 22, 2013

(54) DYE-SENSITIZED PHOTOVOLTAIC DEVICE AND FABRICATION METHOD FOR THE SAME

(71) Applicant: Rohm Co., Ltd., (US)

(72) Inventor: Toshihiro Kimura, Kyoto (JP)

(73) Assignee: ROHM CO., LTD., Kyoto (JP)

(21) Appl. No.: 13/772,313

(22) Filed: Feb. 20, 2013

(30) Foreign Application Priority Data
Feb. 21, 2012 (JP) 2012-035148

(51) Int. Cl. H01G 9/20; H01L 31/18

(52) U.S. Cl. CPC H01G 9/2027; H01L 31/1884
USPC 136/259; 438/98

(57) ABSTRACT

There is provided a dye-sensitized photovoltaic device, which can achieve low-resistivity of an optical transparent electrode film composing first and second electrodes and can improve photovoltaic power generation characteristics, includes: a first substrate; a first electrode disposed on the first substrate; a catalyst layer formed on the first electrode and having a catalytic activity for a redox electrolyte; an electrolysis solution contacted with the catalyst layer and dissolving a redox electrolyte in a solvent; a porous semiconductor layer contacted with the electrolysis solution and including semiconductor fine particles and dye molecules; a second electrode disposed on the porous semiconductor layer; a second substrate disposed on the second electrode; and a sealant disposed between the first and second substrates, and sealing the electrolysis solution. The first and second electrodes are composed of an annealed layer of an ITO fine particles contained film coated on the first and second substrates.

### CROSS REFERENCE TO RELATED APPLICATIONS AND INCORPORATION BY REFERENCE

This application is based upon and claims the benefits of priority from prior Japanese Patent Application No. P2012-035148 filed on Feb. 21, 2012, the entire contents of which are incorporated herein by reference.

### TECHNICAL FIELD

The present invention relates to a dye-sensitized photovoltaic device (Dye-sensitized Solar Cells (DSC)) and a fabrication method for the same. In particular, the present invention relates to a dye-sensitized photovoltaic device which can improve power generation characteristics, and to a fabrication method of such a dye-sensitized photovoltaic device.

### BACKGROUND ART

In recent years, the DSC has received attention as an inexpensive and high-performance photovoltaic device (solar cells). The DSC was developed by Graetzel at Ecole Polytechnique Federale de Lausanne in Switzerland. A titanium oxide which supports sensitizing dyes on the surface thereof is used for the DSC. Accordingly, since the DSC has advantages, such as high in photoelectric conversion efficiency and a low manufacturing cost, it is expected as a next-generation photovoltaic device. Since this photovoltaic device encapsulates an electrolysis solution with the inside, it is also designated as a wet photovoltaic device.

The DSC includes: a working electrode including a porous titanium oxide layer which supports sensitizing dyes on the surface thereof; a counter electrode disposed as opposed to the titanium oxide layer of the working electrode; and an electrolyte filled up between the working electrode and the counter electrode (for example, refer to Patent Literature 1.).

### CITATION LIST

Patent Literature 1: Japanese Patent Application Laying-Open Publication No. H11-135817

### SUMMARY OF THE INVENTION

### Technical Problem

By the way, in the DSC, the working electrode and the counter electrode are composed of an optical transparent electrode film (Indium Tin Oxide (ITO)) so that external light can be received into the cell.

Conventionally, the ITO was generally coated by sputtering which needs vacuum facilities.

A flat film with a comparatively large area is formed by such sputtering. Accordingly, if the DSC was fabricated using the ITO formed by the sputtering, there was the difficulty that additional processing, such as laser processing, photo etching processing, etc., was required, and therefore a manufacturing cost increases.

On the other hand, there has been also proposed a technology for forming films with a paste containing nanoparticles of the ITO using a method of screen printing at a relatively low cost of.

However, low-resistivity equivalent to the sputtered ITO film was difficult in the conventional ITO nanoparticle film.

Moreover, since the specific surface area of the ITO nanoparticles is large remarkably compared with the sputtered ITO film, there was the problem that a reverse current from the nanoparticles to the electrolysis solution is increased, and thereby photovoltaic power generation characteristics is reduced (in particular open circuit voltage is reduced).

The present invention is achieved to solve the problems mentioned above, and the object of the present invention is to provide: a dye-sensitized photovoltaic device which can achieve the low-resistivity of the optical transparent electrode film and improve the photovoltaic power generation characteristics; and a fabrication method of such a dye-sensitized photovoltaic device.

### Solution to Problem

According to an aspect of the present invention, there is provided a dye-sensitized photovoltaic device comprising: a first substrate; a first electrode disposed on the first substrate; a catalyst layer formed on the first electrode, the catalyst layer having a catalytic activity for a redox electrolyte; an electrolysis solution configured to be contacted with the catalyst layer and to dissolve the redox electrolyte in a solvent; a porous semiconductor layer configured to be contacted with the electrolysis solution and to include semiconductor fine particles and dye molecules; a second electrode disposed on the porous semiconductor layer; a second substrate disposed on the second electrode; and a sealant disposed between the first substrate and the second substrate, and sealing the electrolysis solution, wherein the first electrode and the second electrode are composed of an annealed layer of an ITO fine particles contained film coated on the first substrate and the second substrate.

According to another aspect of the present invention, there is provided a fabrication method of a dye-sensitized photovoltaic device comprising: forming an ITO fine particles contained film on a first substrate; performing air annealing of the ITO fine particles contained film on the first substrate at a temperature not more than the melting point of the first substrate; adding an anneal process to the ITO fine particles contained film on the first substrate under N₂ atmosphere at a temperature not more than the melting point of the first substrate to form a first electrode, after the air annealing; forming a conductive thin film as a catalyst layer on the first electrode; adding an anneal process to the ITO fine particles contained film under the N₂ atmosphere again in the formation of the electrical conductivity thin film, in order to achieve low-resistivity of the ITO fine particles having high resistance; forming an ITO fine particles contained film including the ITO fine particles on the second substrate; performing air annealing of the ITO fine particles contained film on the second substrate at a temperature not more than the melting point of the second substrate; forming a block layer; adding an anneal process to the ITO fine particles contained film on the second substrate at a temperature not more than the melting point of the first substrate under N₂ atmosphere to form a second electrode; forming a porous semiconductor layer including semiconductor fine particles on the second electrode; adding an anneal process to the ITO fine particles contained film under the N₂ atmosphere again in the formation of the porous semiconductor layer, in order to achieve low-resistivity of the ITO fine particles having high resistance; impregnating the porous semiconductor layer with a dye solution to adsorbing dye molecules; bonding a counter electrode substrate in which the first electrode and the catalyst layer are formed on the first substrate, and a working electrode substrate in which the second electrode and the porous semiconductor layer to which the dye molecules are adsorbed are formed, via a sealant; and

injecting an electrolysis solution between the counter electrode substrate and the working electrode substrate.

According to still another aspect of the present invention, there is provided a fabrication method of a dye-sensitized photovoltaic device comprising: forming an ITO fine particles contained film on a first substrate; performing air annealing of the ITO fine particles contained film on the first substrate at a temperature not more than the melting point of the first substrate; adding an anneal process to the ITO fine particles contained film on the first substrate under N₂ atmosphere at a temperature not more than the melting point of the first substrate to form a first electrode, after the air annealing; forming a conductive thin film as a catalyst layer on the first electrode; adding an anneal process to the ITO fine particles contained film under the N₂ atmosphere again in the formation of the electrical conductivity thin film, in order to achieve low-resistivity of the ITO fine particles having high resistance; forming an ITO fine particles contained film including the ITO fine particles on the second substrate; performing air annealing of the ITO fine particles contained film on the second substrate at a temperature not more than the melting point of the second substrate; forming a block layer; adding an anneal process to the ITO fine particles contained film on the second substrate at a temperature not more than the melting point of the first substrate under N₂ atmosphere to form a second electrode; forming a porous semiconductor layer including semiconductor fine particles on the second electrode; adding an anneal process to the ITO fine particles contained film under the N₂ atmosphere again in the formation of the porous semiconductor layer, in order to achieve low-resistivity of the ITO fine particles having high resistance; impregnating the porous semiconductor layer with a dye solution to adsorbing dye molecules; bonding a counter electrode substrate in which a plurality of the first electrodes and a plurality of catalyst layers are formed on the first substrate and, a working electrode substrate in which a plurality of the second electrodes and a plurality of the porous semiconductor layers to which the dye molecules are adsorbed are formed on the second substrate via a sealant, so that the cells respectively to be the dye-sensitized photovoltaic devices are divided in each other; forming scribe lines for separating for every cell respectively to be the dye-sensitized photovoltaic devices on the first substrate or the second substrate; breaking the cells to be separated along the scribe lines; and implanting an electrolysis solution into each cell of the separated dye-sensitized photovoltaic device.

### Advantageous Effects of Invention

According to the present invention, there can be provided the dye-sensitized photovoltaic device, which can achieve low-resistivity of the optical transparent electrode film and can also improve photovoltaic power generation characteristics; and a fabrication method of such a dye-sensitized photovoltaic device.

### BRIEF DESCRIPTION OF DRAWINGS

FIG. 1 is a schematic cross-sectional structure diagram showing a dye-sensitized photovoltaic device according to a first embodiment.

FIG. 2 is a schematic configuration diagram showing semiconductor fine particles of a porous semiconductor layer shown in FIG. 1.

FIG. 3 is an operational principle explanatory diagram of the dye-sensitized photovoltaic device according to the first embodiment.

FIG. 4 is an operational principle explanatory diagram showing the dye-sensitized photovoltaic device according to the first embodiment, and is an explanatory diagram showing an internal structure of the dye-sensitized photovoltaic device 200 shown in FIG. 3 in further detail.

FIG. 5 is an explanatory diagram of an operational principle based on a charge exchange reaction in an electrolysis solution of the dye-sensitized photovoltaic device according to the first embodiment.

FIG. 6 is an energy potential diagram between a porous semiconductor layer (12)/dye molecules (32)/an electrolysis solution (14) in the dye-sensitized photovoltaic device according to the first embodiment.

FIG. 7 is an energy potential diagram between the dye molecules (32)/the electrolysis solution (14) in the dye-sensitized photovoltaic device according to the first embodiment, and is an enlarged drawing showing a portion J shown in FIG. 6.

FIG. 8 is an schematic cross-sectional structure diagram showing a configuration example of the dye-sensitized photovoltaic device according to the first embodiment.

FIG. 9 is an enlarged drawing showing a portion A shown in FIG. 8.

FIG. 10 is an enlarged drawing showing a portion B shown in FIG. 8.

FIG. 11A is a schematic diagram showing an ITO film as a comparative example.

FIG. 11B is a schematic diagram showing an ITO film in the dye-sensitized photovoltaic device according to the first embodiment.

FIG. 12 is a schematic cross-sectional structure diagram showing a configuration example of the dye-sensitized photovoltaic device according to the first embodiment.

FIG. 13 is an explanatory diagram showing the state of a back transfer of electrons in the ITO film.

FIG. 14 is a graphic chart showing a relationship between an in-plane sheet resistance and an annealing temperature with regard to the ITO nanoparticle film.

FIG. 15A is a table showing detailed conditions ((1) to (6)) with regard to the graphic chart of FIG. 14.

FIG. 15B is a table showing detailed conditions ((7) to (10)) with regard to the graphic chart of FIG. 14.

FIG. 16 is a graphic chart showing a relation between the transmittances and wavelengths of sputtered ITO films according to a comparative example, and a relation between the transmittances and wavelengths of ITO nanoparticle films applied to the dye-sensitized photovoltaic device according to the first embodiment.

FIG. 17A is a bird's-eye view configuration diagram showing a fabricating process for forming an ITO fine particles contained film on a first substrate or a second substrate of the dye-sensitized photovoltaic device according to the first embodiment.

FIG. 17B is a bird's-eye view configuration diagram showing a fabricating process for forming an optical semiconductor film on the first substrate shown in FIG. 17A.

FIG. 17C is a bird's-eye view configuration diagram showing an aspect of forming a porous optical semiconductor film on the first substrate shown in FIG. 17B.

FIG. 17D is a bird's-eye view configuration diagram showing a process for impregnating the porous semiconductor layer shown in FIG. 17C with a dye solution.

FIG. 18A is a bird's-eye view configuration diagram showing a fabricating process for forming a catalyst film on the second substrate on which the ITO fine particles contained film is already formed.

FIG. 18B is a bird's-eye view configuration diagram showing an aspect of forming the catalyst layer on the second substrate having an injection hole and an air vent hole.

FIG. 19A is a bird's-eye view configuration diagram showing the state of bonding between a working electrode and a counter electrode via a sealant, as one process in the fabricating process of the dye-sensitized photovoltaic device according to the first embodiment.

FIG. 19B is a bird's-eye view configuration diagram showing the state of injecting an electrolysis solution as one process in the fabricating process of the dye-sensitized photovoltaic device according to the first embodiment.

FIG. 19C is a schematic cross-sectional structure diagram showing the fabricated dye-sensitized photovoltaic device according to the first embodiment.

FIG. 20A is a photographic view showing a cross-sectional shape of the ITO nanoparticle film.

FIG. 20B is a photographic view in which the ITO nanoparticles shown in FIG. 20A are enlarged partially.

FIG. 20C is a photographic view showing a surface shape of the ITO nanoparticle film.

FIG. 20D is a photographic view in which the ITO nanoparticles shown in FIG. 20B are enlarged partially.

FIG. 21 is a graphic chart showing photovoltaic power generation characteristics (relationship between current density and voltage) with regard to the ITO film according to the comparative example, and photovoltaic power generation characteristics (relationship between current density and voltage) with regard to the ITO film applied to the dye-sensitized photovoltaic device according to the first embodiment.

FIG. 22 is a graphic chart showing photovoltaic power generation characteristics (relationship between current density and voltage) with regard to the ITO film according to the comparative example, and photovoltaic power generation characteristics (relationship between current density and voltage) with regard to the ITO film applied to the dye-sensitized photovoltaic device according to the first embodiment.

FIG. 23 is a graphic chart showing the photovoltaic power generation characteristics (relationship between current density and voltage) in the case of forming a block layer on the ITO nanoparticles, and in the case of not forming the block layer thereon.

FIG. 24 is a schematic diagram showing the state of not forming the block layer on the ITO nanoparticles.

FIG. 25 is a schematic diagram showing the state of forming the block layer on the ITO nanoparticles.

FIG. 26 is a top view diagram showing the state of forming a plurality of second electrodes on the second substrate in a fabrication method of a dye-sensitized photovoltaic device according to a second embodiment.

FIG. 27 is a top view diagram showing the state of forming a plurality of first electrodes on the first substrate, as one process in the fabrication method of the dye-sensitized photovoltaic device according to the second embodiment.

FIG. 28 is a top view diagram showing the state of bonding between a working electrode and a counter electrode via a sealant, as one process in the fabrication method of the dye-sensitized photovoltaic device according to the second embodiment.

FIG. 29 is a schematic cross-sectional structure diagram showing the dye-sensitized photovoltaic device taken in the line I-I of FIG. 28, in the fabrication method of the dye-sensitized photovoltaic device according to the second embodiment.

FIG. 30 is a top view diagram showing the state of forming a horizontal scribe line, as one process in the fabrication method of the dye-sensitized photovoltaic device according to the second embodiment.

FIG. 31 is a top view diagram showing the state of further forming a longitudinal scribe line, as one process in the fabrication method of the dye-sensitized photovoltaic device according to the second embodiment.

### DESCRIPTION OF EMBODIMENTS

Next, embodiments of the invention will be described with reference to drawings. In the description of the following drawings, the identical or similar reference numeral is attached to the identical or similar part. However, it should be known about that the drawings are schematic and the relation between thickness and the plane size and the ratio of the thickness of each layer differs from an actual thing. Therefore, detailed thickness and size should be determined in consideration of the following explanation. Of course, the part from which the relation and ratio of a mutual size differ also in mutually drawings is included.

Moreover, the embodiments shown hereinafter exemplify the apparatus and method for materializing the technical idea of the present invention; and the embodiments of the present invention does not specify the material, shape, structure, placement, etc. of component parts as the following. Various changes can be added to the technical idea of the present invention in scope of claims.

In dye-sensitized photovoltaic device(s) according to the following embodiments, “transparent” is defined as that whose transmissivity is not less than approximately 50%. In the dye-sensitized photovoltaic device(s) according to the embodiments, the “transparent” is used for the purpose of being transparent and colorless with respect to visible light. The visible light is equivalent to light having a wavelength of approximately 360 nm to approximately 830 nm and energy of approximately 3.4 eV to approximately 1.5 eV, and it can be said that it is transparent if the transmission rate is not less than 50% in such a region.

### First Embodiment

### Dye-Sensitized Photovoltaic Device

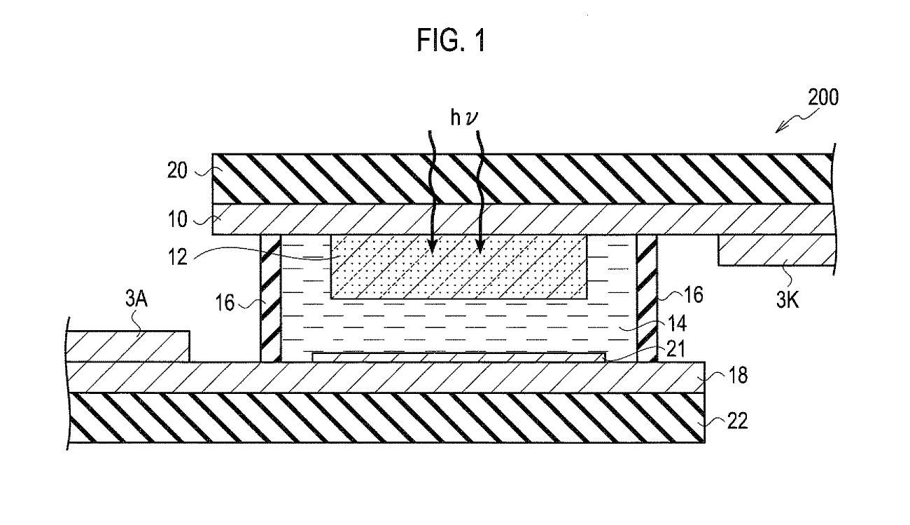

A schematic cross-sectional structure showing a dye-sensitized photovoltaic device 200 according to a first embodiment is illustrated as shown in FIG. 1.

As shown in FIG. 1, the dye-sensitized photovoltaic device 200 according to the first embodiment includes: a glass substrate 22 as a first substrate; a first electrode 18 composed of an annealed layer of an ITO fine particles contained film and disposed on the glass substrate 22; a catalyst layer 21 disposed on the first electrode 18; and a charge transport layer 14 contacted with the catalyst layer 21 and including an electrolyte made by mixing two or more types of redox electrolytes with a solvent.

As shown in FIG. 1, the dye-sensitized photovoltaic device 200 further includes:

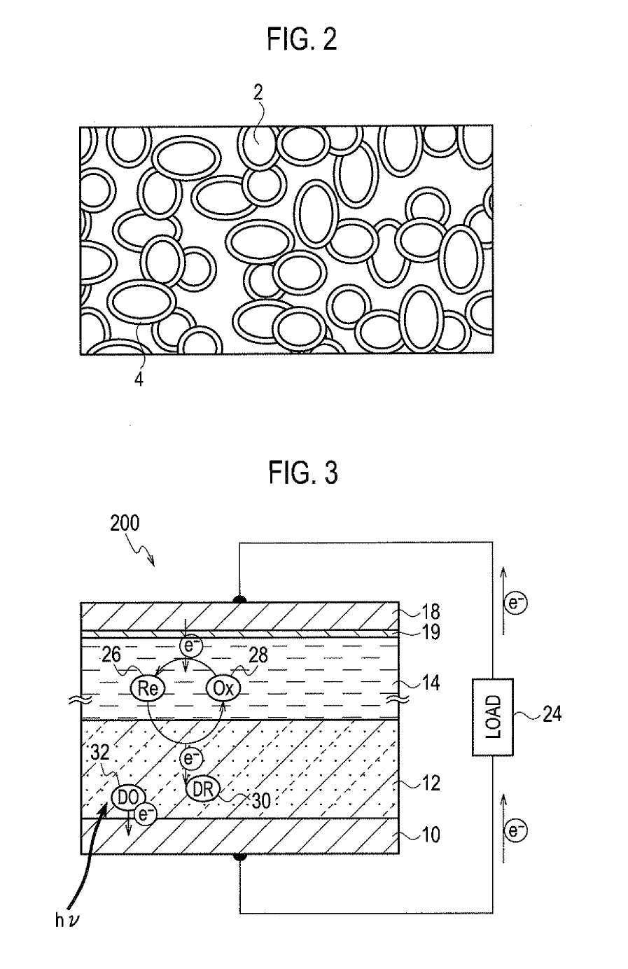

a glass substrate 20 as a second substrate; a transparent electrode 10 as a second electrode, composed of an annealed layer of an ITO fine particles contained film, and disposed on the second substrate 20; a porous semiconductor layer 12 including semiconductor fine particles 2 and dye molecules 4 as shown in FIG. 2, and disposed on the transparent electrode 10; an electrolysis solution 14 contacted with the porous semiconductor layer 12 and dissolving a redox electrolyte in a solvent; a first electrode 18 contacted with the electrolysis solution 14; a first substrate 22 disposed on the first electrode 18; and a sealant 16 for sealing the electrolysis solution 14, wherein the sealant 16 is disposed between the second substrate 20 and the first substrate 22.

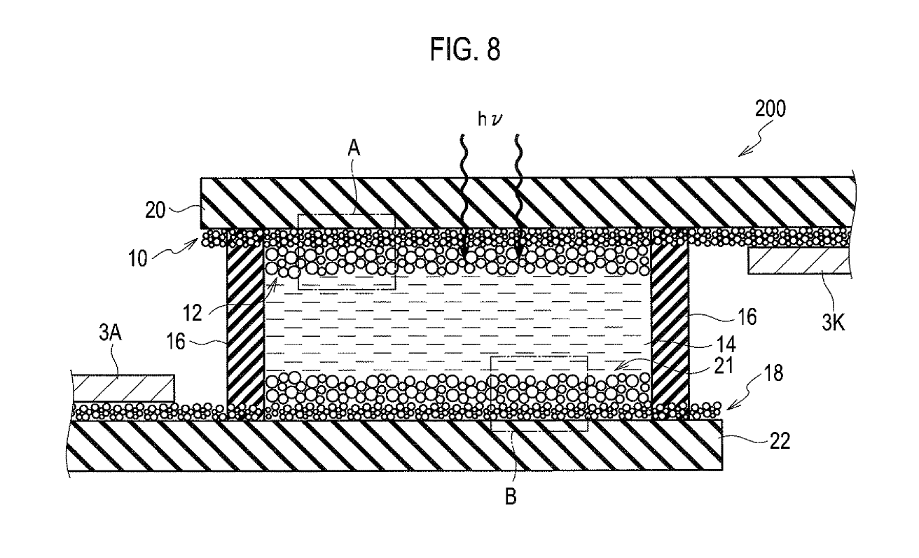

Detailed configuration examples of the first electrode 18 and the transparent electrode 10 which are composed of the annealed layer of the ITO fine particles contained film will be later described referring FIGS. 8-10.

A schematic structure showing the semiconductor fine particles 2 of the porous semiconductor layer 12 shown in FIG. 1 is illustrated as shown in FIG. 2. As shown in FIG. 2, in the porous semiconductor layer 12, the semiconductor fine particles 2 composed of TiO₂ etc. form a complicated network by being combined with each other. The dye molecules 4 are adsorbed on a surface of the semiconductor fine particles 2. In the porous semiconductor layer 12, there are plenty of not more than 100-nm fine pores.

### (Operational Principle)

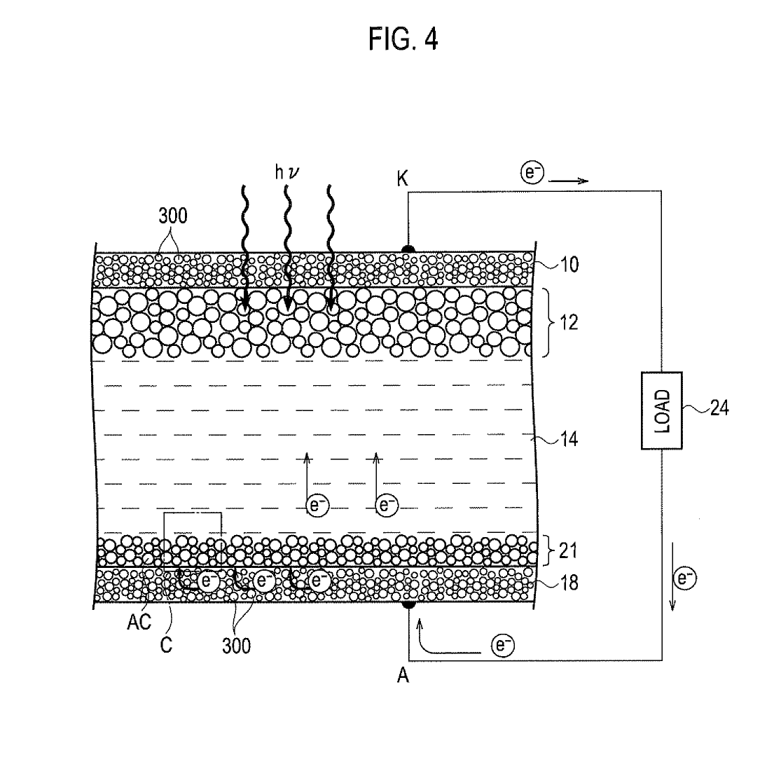

The operational principle of the dye-sensitized photovoltaic device 200 according to the first embodiment is illustrated as shown in FIG. 3. FIG. 4 is a diagram showing the operational principle of the dye-sensitized photovoltaic device 200 according to the first embodiment, and is a diagram which illustrates an internal structure of the dye-sensitized photovoltaic device 200 shown in FIG. 3 still in detail.

Electromotive force is generated since the following reactions (a) to (d) occur continuously, and then an electric current conducts to a load 24.

(a) Dye molecules 32 in the porous semiconductor layer 12 absorb the photons (hν), the electrons (e⁻) are released, and then the dye molecules 32 are become to oxidant DO.
(b) Redox electrolyte 26 of reductant illustrated with Re is diffused in the porous semiconductor layer 12, and is close to the dye molecules 32 of the oxidant illustrated with DO.
(c) The electrons (e⁻) are supplied to the dye molecules 32 from the redox electrolyte 26. The redox electrolyte 26 becomes a redox electrolyte 28 of the oxidant illustrated with Ox, and the dye molecules 32 become a reduced dye molecules 30 illustrated with DR.
(d) The redox electrolyte 28 is diffused in a direction of the first electrode 18, and the electrons are supplied from the first electrode 18 thereto due to a catalytic action of platinum or activated carbon in the catalyst layer 21. The redox electrolyte 28 then becomes the reductant redox electrolytes 26 illustrated with Re.

The redox electrolyte 26 needs to be close near the dye molecules 32, being diffused into the complicated space in the porous semiconductor layer 12.

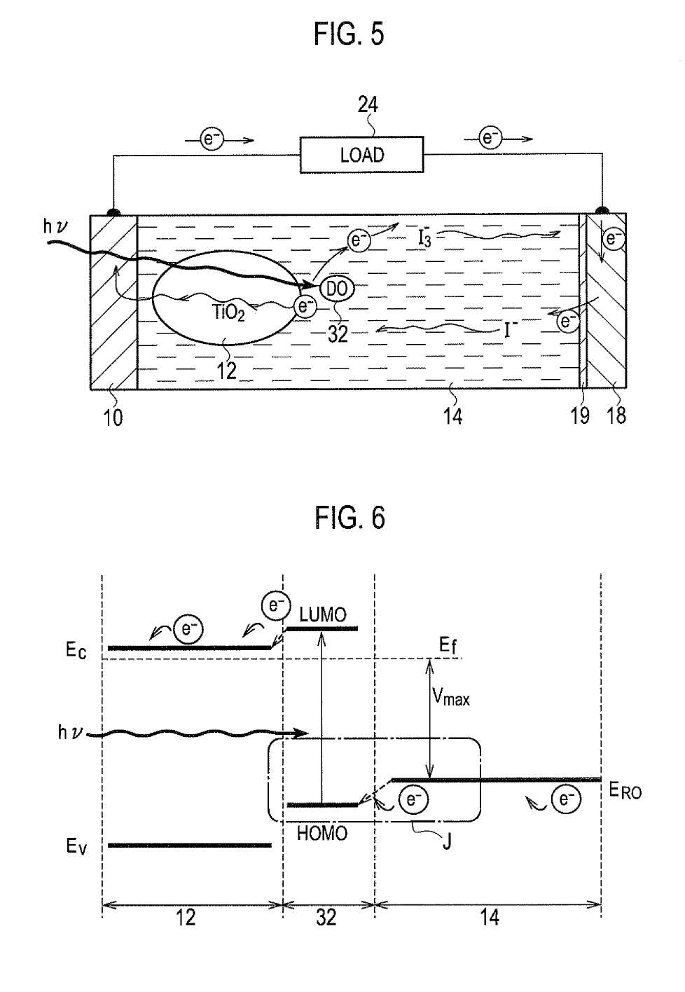

The operational principle based on a charge exchange reaction in the electrolysis solution 14 of the dye-sensitized photovoltaic device 200 according to the first embodiment is illustrated as shown in FIG. 5.

First of all, if light is irradiated from an outside, the photons (hν) react with the dye molecules 32, and then the dye molecules 32 shifts from the ground state to the excited state. The excited electrons (e⁻) generated at this time are injected into a conduction band of the porous semiconductor layer 12 composed of TiO₂. The electrons (e⁻) which conduct into the porous semiconductor layer 12 conduct from the transparent electrode 10 into the load 24 of the external circuit, and then travel to the first electrode 18. The electrons (e⁻) injected into the electrolysis solution 14 from the first electrode 18 are subjected to charge exchange with an iodine redox electrolyte (I⁻/I₃⁻) in the electrolysis solution 14. The iodine redox electrolyte (I⁻/I₃⁻) is diffused into the electrolysis solution 14, and then re-reacts with the dye molecules 32. In this case, the charge exchange reaction proceeds in accordance with 3I⁻→I₃⁻+2e⁻ in the dye molecules surface, and proceeds in accordance with I₃⁻+2e⁻→3I⁻ in the first electrode 18.

Acetonitrile is used for the electrolysis solution 14 as a solvent, for example, and iodine is present as the iodine redox electrolyte I₃⁻ in the electrolysis solution 14 as an electrolyte in this case, for example. Furthermore, Iodide salt (lithium iodide, potassium iodide, etc.) as an electrolyte is present as the iodine redox electrolyte I⁻ in the electrolysis solution 14, for example. Moreover, in the electrolysis solution 14, an additive agent (e.g., tert-butyl pyridine (TBP)) may be applied as a reverse electron transfer inhibiting solution.

The electrolysis solution 14 can be composed by dissolving the solute and the additive agent in the solvent (acetonitrile). The above-mentioned materials are applicable to a wet DSC etc., and composite materials are different therefrom when using the ambient temperature molten salt (ionic liquid) and the solid electrolyte.

In the dye-sensitized photovoltaic device 200 according to the first embodiment, the solvent is a liquid for dissolving electrolytes and additive agents described later, and is preferable to have high chemical stability with high boiling point, and to have high dielectric constant (the electrolyte can be completely dissolved) and low viscosity. The solvent may be composed of acetonitrile, propylene carbonate, γ-butyrolactone (kigoudayp), methoxyacetonitrile, propionitrile, ethylene carbonate, propylene carbonate, etc., for example.

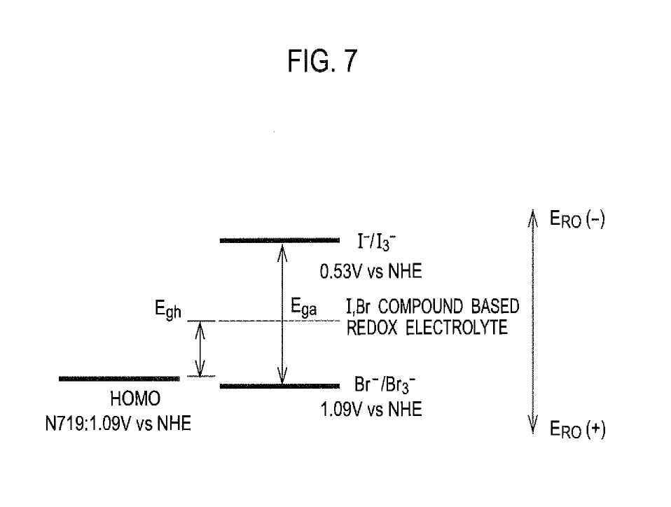

In the dye-sensitized photovoltaic device 200 according to the first embodiment, an energy potential diagram between the porous semiconductor layer (12)/the dye molecules (32)/the electrolysis solution (14) is illustrated as shown in FIG. 6. Moreover, an energy potential diagram between the dye molecules (32)/the electrolysis solution (14), which is an enlarged drawing of a portion J shown in FIG. 6, is illustrated as shown in FIG. 7.

If light is irradiated from an outside, the photons (hν) react with the dye molecules 32, and then the dye molecules 32 shifts from the ground state HOMO to the excited state LUMO. The excited electrons (e⁻) generated at this time are injected into a conduction band of the porous semiconductor layer 12 composed of TiO₂. The electrons (e⁻) which conduct into the porous semiconductor layer 12 conduct from the transparent electrode 10 into the load 24 of the external circuit, and then travel to the first electrode 18. The electrons (e⁻) injected into the electrolysis solution 14 from the first electrode 18 are subjected to charge exchange with an iodine compound based redox electrolyte in the electrolysis solution 14. The iodine-bromine compound based oxidation reduction electrolyte is diffused in the electrolysis solution 14, and then re-reacts with the dye molecules 32.

The potential difference between the redox level E_{RO} of the electrolysis solution 14 and the Fermi level E_{f} of the porous semiconductor layer 12 is the maximal electromotive force V_{MAX}. The value of the maximal electromotive force V_{MAX} changes depending on the redox electrolytes of the electrolysis solution 14. The maximal electromotive force V_{MAX} is 0.9V (I, N719), for example, in the case of the single-based redox electrolyte (iodine redox electrolyte). As shown in FIG. 7, if the electrolysis solution 14 includes an iodine-bromine compound based redox electrolyte, the redox potential of the compound based redox electrolyte can be adjusted to any values within a range between the redox potential of the iodine redox electrolyte and the redox potential of the bromine redox electrolyte by adjusting the mixing ratio thereof.

As shown in FIG. 7, the redox level E_{RO} is 0.53V (I/I₃⁻) if the mixing ratio of the bromine redox electrolyte of the electrolysis solution 14 is zero, but the redox level E_{RO} is 1.09V (Br/Br₃⁻) if the mixing ratio of the iodine redox electrolyte is zero. The value of the gap energy E_{ga} during this period is 1.09−0.53=0.56V.

It becomes voltage loss in view of obtaining the maximal electromotive force V_{MAX}, if the value of the potential difference E_{gh} between the HOMO level and the redox level E_{RO} is large. If the value of the potential difference E_{gh} between the HOMO level and the redox level E_{RO} is low, traveling of the electrons (e⁻) from the electrolysis solution 14 to the dye molecules 32 will be obstructed.

Accordingly, in order to efficiently conduct the electrons (e⁻) from the electrolysis solution 14 to the dye molecules 32 side and to control the voltage loss in view of obtaining the maximal electromotive force V_{MAX}, it is preferable that the level of the redox level E_{RO} is larger than the HOMO level of the dye molecules 32, and the potential difference E_{gh} is set as small as possible.

As stated in the following, in the electrolysis solution composed of the iodine-bromine compound based oxidation reduction electrolyte obtained by mixing the iodine redox electrolyte and the bromine redox electrolyte, the value of the open circuit voltage increases depending on the additive amount of the bromine redox electrolyte, compared with the case where the iodine redox electrolyte is used individually. This is because the redox potential of the bromine redox electrolyte is the positive (positive value) side and the redox potential of the iodine-bromine compound based oxidation reduction electrolyte shifts to the positive (positive value) side depending on the additive amount of the bromine redox electrolyte, compared with the iodine redox electrolyte.

### (Configuration of Dye-Sensitized Photovoltaic Device)

Next, with reference to FIGS. 8-10, there will be explained a configuration example of the dye-sensitized photovoltaic device 200 according to the first embodiment.

As shown in FIG. 8, in the dye-sensitized photovoltaic device 200 according to the first embodiment, the first electrode 18 and the transparent electrode 10 as the second electrode are composed of annealed layers of the ITO fine particles contained films coated on the first substrate 22 and the second substrate 20.

The ITO fine particles contained film is composed by being laminated up to a thickness of not more than 1 μm.

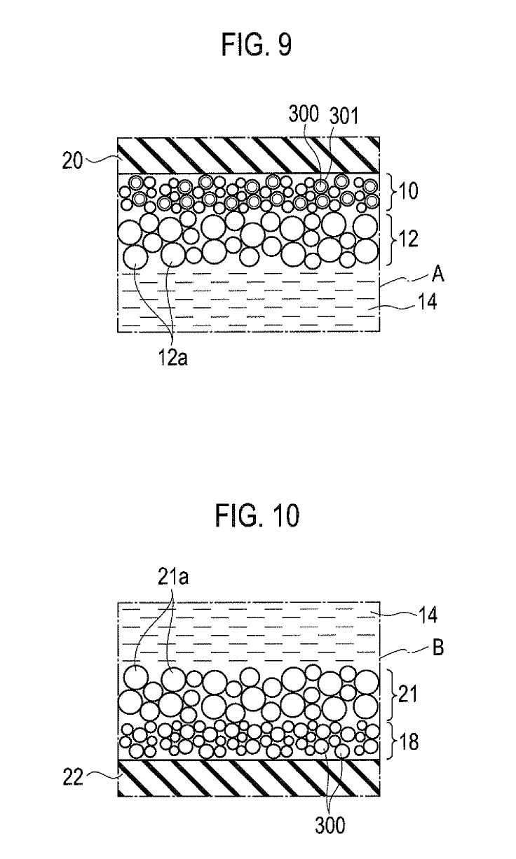

The ITO fine particles contained film is formed by coating a paste in which the ITO fine particles (ITO nanoparticles) 300 (refer to FIGS. 9 and 10) are dispersed (e.g., approximately 900 nm) by using screen printing on the first substrate 22 and the second substrate 20 respectively composed of a glass substrate. Then, the ITO fine particles contained film is subjected to air annealing at a temperature (e.g., 450-550 degrees C.) not more than the melting points of the first substrate 22 and the second substrate 20.

After the air annealing, the ITO fine particles contained film is subjected to the anneal process under the N₂ atmosphere at a temperature (e.g., 450-550 degrees C.) not more than the melting points of the first substrate 22 and the second substrate 20, and thereby the first electrode 18 and the transparent electrode 10 are formed.

The conditions of under N₂ atmosphere is are conditions where N₂ of more than 1 sccm is flowed in the conditions that the oxygen concentration is controlled.

The first electrode 18 and the transparent electrode 10 respectively composed of the annealed layer of the ITO fine particles contained film formed in this manner can be applied into low resistance (approximately 20Ω/□) up to the same level as the sputtered ITO film. Accordingly, the photovoltaic power generation characteristics equivalent to that in the case where the first electrode and the second electrode are formed by using a sputtered ITO film can be obtained. Detailed photovoltaic power generation characteristics will be described later. As shown in FIG. 9, the block layer 301 composed of TiO₂ or Nb₂O₅ etc. is formed in a surface of the ITO fine particles 300 included in the annealed layer formed on the second substrate 20.

In this case, the particle diameter of the ITO fine particles 300 may be 10-20 nm, and the thickness of the block layer 301 may be not more than 10 nm.

The block layer 301 can be formed by coating a precursor solution of TiO₂ or Nb₂O₅ etc. on the surface of the ITO fine particles 300 by using a spin coat method or a dip method.

Accordingly, the reverse current from the ITO fine particles 300 can be reduced, and the open circuit voltage in the dye-sensitized photovoltaic device 200 can be improved remarkable. A concrete example of the open circuit voltage will be described later.

The porous semiconductor layer 12 is composed of semiconductor fine particles which are composed of TiO₂ etc. (refer to FIGS. 8 and 9). More specifically, the porous semiconductor layer 12 can be formed by annealing, after coating a paste 21a including semiconductor fine particles (e.g., TiO₂) on the transparent electrode 10 by using the screen printing.

The catalyst layer 21 is composed of platinum, activated carbon, etc. (refer to FIGS. 8 and 10). More specifically, the catalyst layer 21 can be formed by annealing, after coating a paste including a sputtered platinum film or a platinum precursor, or the paste 21a including the activated carbon and the fine particles of the metal oxide, such as TiO₂, ZnO, SnO₂, and WO₃ etc., on the first electrode 18 by using the screen printing.

(Characteristics of ITO Film according to Comparative Example)

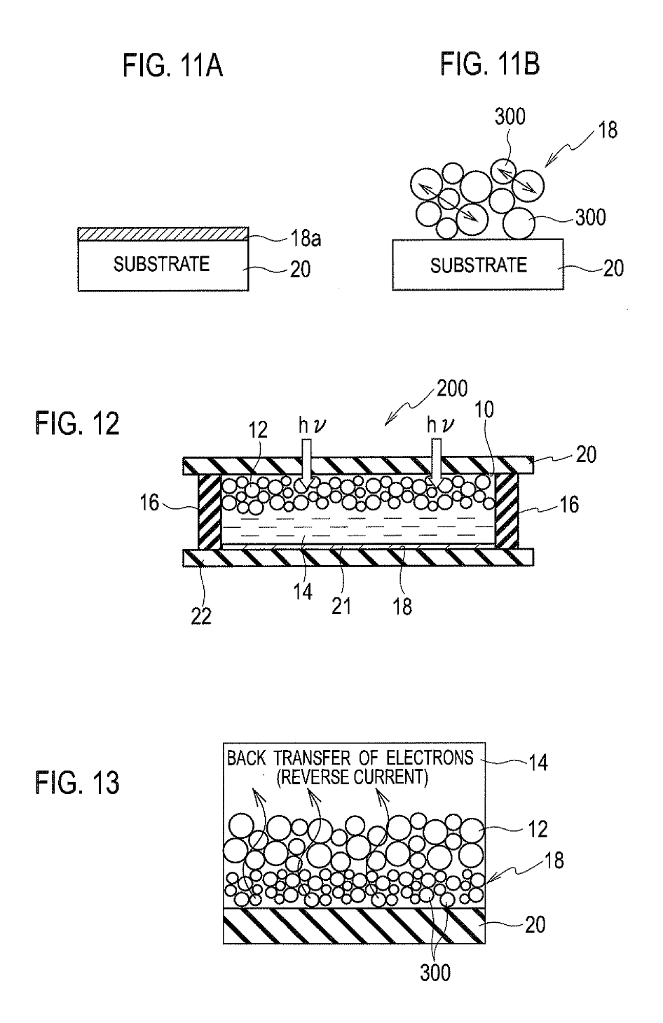

FIG. 11A is a schematic diagram showing an ITO film 18a as a comparative example. Conventionally, the ITO film 18a was generally formed by sputtering which needs vacuum facilities. Since the sputtered ITO film is flat and is a film formed with a comparative large area, there was the problem that additional processing (e.g., photo etching processing which is laser processing and semiconductor process) are required when fabricating the dye-sensitized photovoltaic device and thereby the manufacturing cost increases.

FIG. 11B is a schematic diagram showing the ITO film 18 in the dye-sensitized photovoltaic device according to the first embodiment. The ITO film 18 can be made by annealing at a predetermined atmosphere and temperature conditions, after coating the paste containing the ITO fine particles (ITO nanoparticles) 300 by using the screen film formation, as mentioned above. Thus, the ITO film 18 in the dye-sensitized photovoltaic device according to the first embodiment requires no vacuum facilities. Moreover, since the paste containing the ITO fine particles (ITO nanoparticles) 300 is comparatively affordable price, the manufacturing cost can be reduced remarkable.

Moreover, according to the ITO film 18 in the dye-sensitized photovoltaic device according to the first embodiment, the film formation and the patterning can be performed simultaneously using the mask of a prescribed pattern when forming the film by using the screen printing. Accordingly, the manufacturing cost can be reduced remarkable.

FIG. 12 is a schematic cross-sectional structure diagram showing a configuration example of the dye-sensitized photovoltaic device 200 according to the first embodiment. FIG. 13 is an explanatory diagram showing the state of back transfer of electrons in the ITO film.

As shown in FIG. 13, the transparent electrode 10 which is the ITO nanoparticle film in the dye-sensitized photovoltaic device is present with the particle state. Therefore, in order to form a similar low resistive film as the sputtered ITO film, it is necessary to neck (sinter) a conducting path between the nanoparticles, and to reduce a bulk resistor itself of the ITO fine particles 300.

In a conventional method, the ITO nanoparticle film was formed and was simply sintered. However, because the above-mentioned problem, the sheet resistance became approximately triple-digit increased value, compared with the sputtered ITO film, and therefore the ITO nanoparticle film was not able to use as a transparent conductive film for the dye-sensitized photovoltaic devices.

The specific surface area of the ITO nanoparticles 300 is remarkable larger than that of the sputtered ITO film 400.

Therefore as shown in FIG. 13, there was the problem that if the ITO nanoparticle film was used as the transparent electrode 10 at the side of the working electrode for the dye-sensitized photovoltaic devices, the reverse current CI from the ITO nanoparticles 300 to the electrolysis solution 14 was increased, and the photovoltaic power generation characteristics (in particular open circuit voltage) are reduced.

(ITO Nanoparticle Film in Dye-Sensitized Photovoltaic Device according to First Embodiment)

In order to dissolve the above-mentioned problems, the inventor formed films up to approximately 900 nm by coating pastes in which the ITO nanoparticles 300 were dispersed on the glass substrate by using the screen printing, implemented anneal processes at various temperature conditions, and then confirmed the in-plane sheet resistance.

Consequently, if the ITO nanoparticle film was subjected to air annealing at 450-550 degrees C., the resistance decreased as the temperature rises, but finally the high resistance film which is up to order of 10³ is formed.

Subsequently, as a consequence of adding continuously the anneal process under the N₂ atmosphere (4 l/min), the low-resistivity was able to be up to order of 10¹.

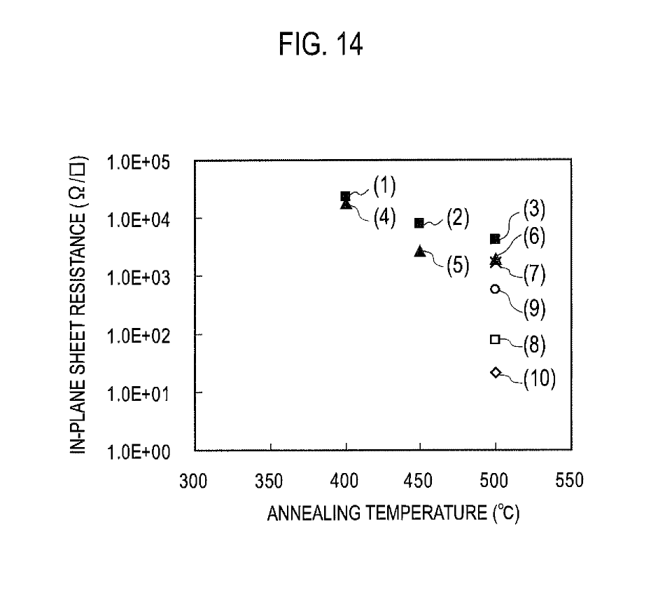

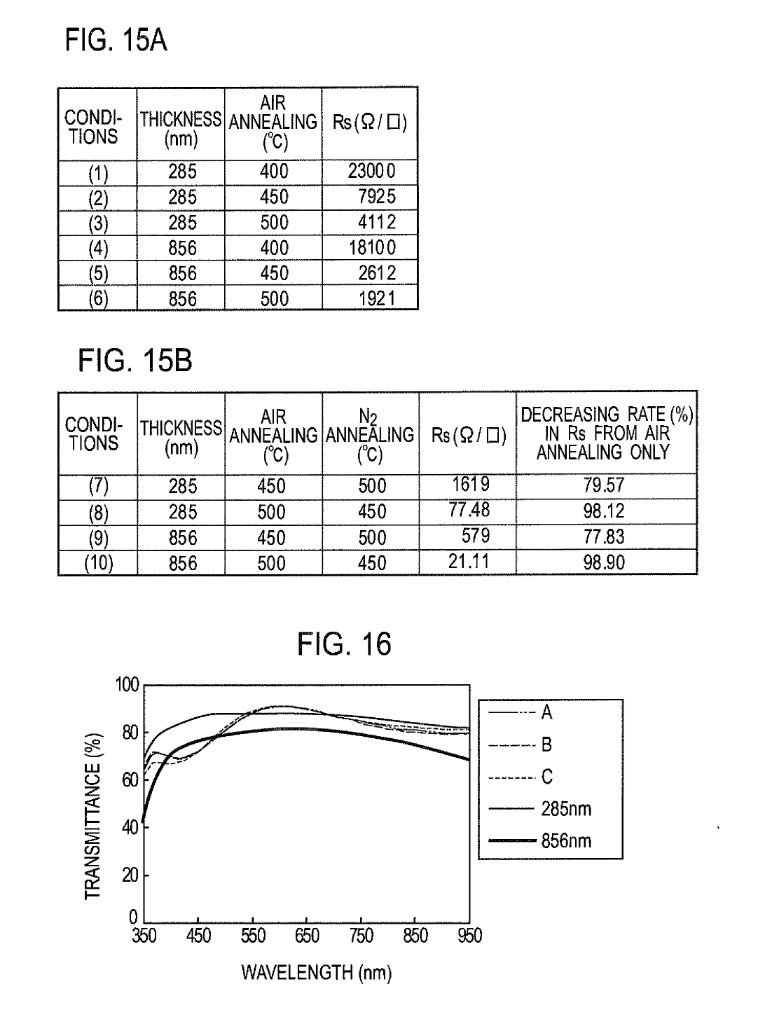

FIG. 14 shows a graphic chart showing a relationship between the in-plane sheet resistance and the annealing temperature with regard to the ITO nanoparticle film. FIGS. 15A and 15B show tables showing the detailed conditions with regard to the graphic chart shown in FIG. 14.

FIGS. 14, 15A and 15B show results of experiments in the following conditions (1) to (10).

The conditions (1) are conditions where the ITO particle thickness is 285 nm and the air annealing temperature is 400 degrees C.

The conditions (2) are conditions where the ITO particle thickness is 285 nm and the air annealing temperature is 450 degrees C.

The conditions (3) are conditions where the ITO particle thickness is 285 nm and the air annealing temperature is 500 degrees C.

The conditions (4) are conditions where the ITO particle thickness is 856 nm and the air annealing temperature is 400 degrees C.

The conditions (5) are conditions where the ITO particle thickness is 856 nm and the air annealing temperature is 450 degrees C.

The conditions (6) are conditions where the ITO particle thickness is 856 nm and the air annealing temperature is 500 degrees C.

The conditions (7) to (10) are conditions where the anneal process under the N₂ atmosphere (4 l/min) continuously is added after the air annealing processing.

The conditions (7) are conditions where the ITO particle thickness is 285 nm, the air annealing temperature is 450 degrees C., and the N₂ annealing temperature is 500 degrees C.

The conditions (8) are conditions where the ITO particle thickness is 285 nm, the air annealing temperature is 500 degrees C., and the N₂ annealing temperature is 450 degrees C.

The conditions (9) are conditions where the ITO particle thickness is 856 nm, the air annealing temperature is 450 degrees C., and the N₂ annealing temperature is 500 degrees C.

The conditions (10) are conditions where the ITO particle thickness is 856 nm, the air annealing temperature is 500 degrees C., and the N₂ annealing temperature is 450 degrees C.

As clearly from the graphic chart shown in FIG. 14, the ITO nanoparticle film in the case of the conditions (10) has lowest resistance.

The details of the conditions (10) are that the film thickness is 856 nm, the air annealing temperature is 500 degrees C., the N₂ annealing temperature is 450 degrees C., Rs (Ω/□) is 21.11, and the decreasing rate (%) in sheet resistance from air annealing only is 98.90%, as shown in FIG. 15B.

The following is understood from the results of the experiments in the conditions (1) to (10).

First of all, it is proved that the ITO nanoparticle film becomes lower resistance as the thickness thereof increases, but the low resistance equivalent to that of the sputtered ITO film is unrealizable merely by the low-resistivity.

Moreover, it is proved that the surface electrical resistance decreases in order of one digit, if the paste in which the ITO nanoparticles are dispersed is subjected to the air annealing at 450-500 degrees C. and then the anneal processed in N₂ atmosphere subsequently.

Moreover, it is proved that the air annealing performed at high temperature is available in the low-resistivity also in the same thermal history. That is, it is proved that a lower-resistance film can be obtained if the anneal process of N₂ atmosphere is performed at 450 degrees C., after the air annealing at 500 degrees C.

It is estimated that the above-mentioned process is available in the low-resistivity of the film since the surface coating film which disperses the ITO nanoparticles is removed.

Moreover, it is proved that to reduce the oxygen as much as possible is available in the low-resistivity of the film when performing the anneal process under the N₂ atmosphere.

It is also proved that the transmittance of the incident visual light range decreases, although the ITO nanoparticle film of which the film thickness is increased to perform the above-mentioned annealing becomes the in-plane sheet resistance equivalent to that of the sputtered ITO film. However, if the ITO nanoparticle film is not more than 1 μm of film thickness, the ITO nanoparticle film is substantially equivalent to the sputtered ITO film.

FIG. 16 shows a graphic chart showing the relation between the transmittance and the wavelength of sputtered ITO films (A) to (C) according to the comparative example, and the relation between the transmittance and the wavelength of an ITO nanoparticle film (of which the film thickness is 285 nm) (D) and an ITO nanoparticle film (of which the film thickness is 856 nm) (E) which are applied to the dye-sensitized photovoltaic device according to the first embodiment.

As clearly from the graphic chart shown in FIG. 16, although there are some superiority or inferiority depending on the wavelengths, the ITO nanoparticle films (D) and (E) achieve equal to or greater than 70% of the transmittance in the range of the wavelengths 450-750 nm.

The transmittance of the ITO nanoparticle film (of which the film thickness is 285 nm) (D) is more excellent than that of the ITO nanoparticle film (of which the film thickness is 856 nm) (E), but the low resistance of the ITO nanoparticle film (of which the film thickness is 856 nm) (E) is more excellent than that of the ITO nanoparticle film (of which the film thickness is 285 nm) (D), as shown in FIGS. 14, 15A and 15B.

### (Fabrication Method of Dye-Sensitized Photovoltaic Device)

The dye-sensitized photovoltaic device 200 according to the 1st embodiment is fabricated by the following processes (a) to (l):

(a) The process of forming a film containing the ITO fine particles 300 on the first substrate 22;
(b) The process of performing air annealing of the ITO fine particles contained film at a temperature not more than the melting point of the first substrate 22;
(c) The process of adding an anneal process to the ITO fine particles contained film at the temperature not more than the melting point of the first substrate 22 under the N₂ atmosphere after the air annealing, and forming the first electrode 18,
(d) The process of forming a conductive thin film as the catalyst layer 21 on the first electrode 18;
(e) The process of forming an ITO fine particles contained film including the ITO fine particles 300 on which the block layer 301 is formed, on the second substrate 20;
(f) The process of performing air annealing of the ITO fine particles contained film at the temperature not more than the melting point of the second substrate 20;
(g) The process of adding the anneal process to the ITO fine particles contained film at a temperature not more than the melting point of the first substrate under the N₂ atmosphere after the air annealing, and forming the second electrode 10;
(h) The process of forming the block layer 301 in the layer of the ITO fine particles 300;
(i) The process of forming the porous semiconductor layer 12 including semiconductor fine particles on the second electrode 10;
(j) The process of impregnating the porous semiconductor layer 12 with the dye solution to adsorbing dye molecules;
(k) The process of bonding a counter electrode substrate in which the first electrode 18 and the catalyst layer 21 are formed on the first substrate 22, and a working electrode substrate in which the second electrode 10 and the porous semiconductor layer 12 to which the dye molecules are adsorbed are formed, via the sealant 16; and
(l) The process of injecting the electrolysis solution 14 between the counter electrode substrate and the working electrode substrate.

The process of forming the ITO fine particles contained film on the first substrate 22 may be the process coating the paste including the ITO fine particles 300 on the first substrate 22.

Moreover, the process of forming the ITO fine particles contained film including the ITO fine particles 300 on the second substrate 20 may be the process coating the paste including the ITO fine particles 300 on the second substrate 20.

Moreover, the first substrate 22 and the second substrate 20 may be composed of a soda-lime glass etc., and the temperature not more than the melting point may be 450-550 degrees C.

Moreover, the conditions under the N₂ atmosphere may be conditions of flowing N₂ of more than 1 sccm in the conditions where the oxygen concentration is controlled.

Moreover, the block layer 301 as shown in FIG. 9 may be formed by coating a precursor solution of TiO₂ or Nb₂O₅ etc. on the surface of the ITO fine particles 300 by using a spin coat method or a dip method.

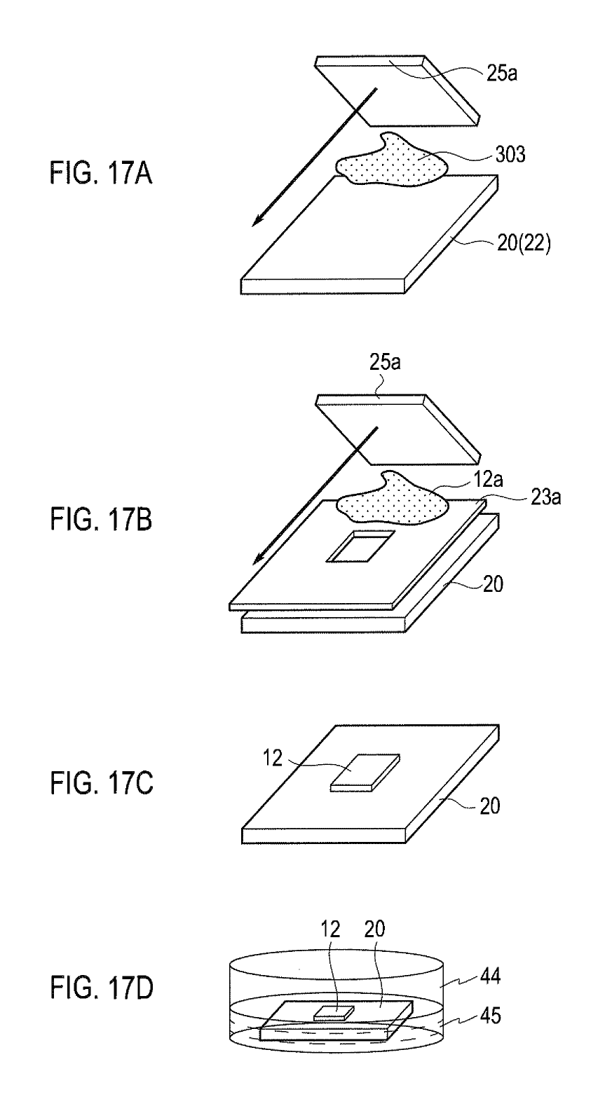

Next, with reference to FIGS. 17-19, there will be explained an example of the detailed fabrication method of the dye-sensitized photovoltaic device 200 according to the first embodiment.

First of all, with reference to FIG. 17A, an example of forming the ITO nanoparticle film with the screen printing will be explained.

As shown in FIG. 17A, a specified quantity of the paste 303 in which the ITO fine particles (ITO nanoparticles) 300 (refer to FIGS. 9 and 10) are dispersed is deposited on the first substrate 22 or the second substrate 20.

Subsequently, a squeegee 25a is shifted to an arrow direction, and the paste 303 is coated on the surface of the first substrate 22 or the second substrate 20.

The coating process is performed several times so that the thickness of the paste 303 may be up to a target thickness.

Next, the paste layer coated on the first substrate 22 or the second substrate 20 is subjected to the air annealing at the temperature not more than the melting point of the first substrate 22 or the second substrate 20.

If the first substrate 22 and the second substrate 20 are composed of a soda-lime glass, the temperature not more than the melting point may be 450-550 degrees C. Moreover, if the first substrate 22 and the second substrate 20 are composed of substances having high-melting points (e.g., non-alkali glass, silica glass), the annealing can also be performed equal to or greater than 550 degrees C.

It is confirmed experimentally that, for the air annealing, the anneal processing at higher temperature is available in the low-resistivity of the ITO fine particles contained film.

The block layer is formed by coating the precursor solution (e.g., TiO₂ or Nb₂O₅ etc.) on the second substrate 20 by using a spin coat method or a dip dryness method. The particle diameter of the ITO fine particles 300 may be 10-20 nm, and the thickness of the block layer 301 may be not more than 10 nm.

The reverse current from the ITO fine particles 300 can be reduced by using the ITO fine particles 300 on which the block layer 301 is formed, and the open circuit voltage in the dye-sensitized photovoltaic device 200 can be improved remarkable. A concrete example of the open circuit voltage will be described later.

Next, after the air annealing, the ITO fine particles contained film is subjected to the anneal process under the N₂ atmosphere at the temperature not more than the melting points of the first substrate 22 or the second substrate 20, and thereby the first electrode 18 or the transparent electrode 10 are formed.

If the first substrate 22 and the second substrate 20 are composed of the soda-lime glass, the temperature not more than the melting point may be 450-550 degrees C. Moreover, if the first substrate 22 and the second substrate 20 are composed of substances having high-melting points (e.g., non-alkali glass, silica glass), the annealing process can also be performed equal to or greater than 550 degrees C.

Next, with reference to FIGS. 17B-17D, an example of forming the porous semiconductor layer 12 with the screen printing will be explained.

As shown in FIG. 17B, a mask member 23a having an aperture corresponding to the porous semiconductor layer to be formed is aligned to set on the second substrate 20 after forming the transparent electrode 10. The thickness of the mask member 23a may be selected in accordance with a target thickness of the porous semiconductor layer to be formed.

Subsequently, the paste 12a including fine particles (e.g., TiO₂, ZnO, WO3, InO₃, ZrO₂, Ta₂O₃, Nb₂O₃, SnO₂, etc.) is coated on the mask member 23a, and the squeegee 25a is shifted to an arrow direction so that the paste 12a is filled up in the aperture of the mask member 23a.

Next, as shown in FIG. 17C, after removing the mask member 23a therefrom, the porous semiconductor layer 12 is formed by annealing the paste layer at a predetermined temperature.

At this point, although the ITO fine particles may become a higher resistance film after the air annealing, the low-resistivity of the film may be achieved by performing the anneal processing under the N₂ atmosphere again.

Subsequently, as shown in FIG. 17D, dyes are adsorbed on the porous semiconductor layer 12 by impregnating the porous semiconductor layer 12 with the dye solution 45 in a container 44.

Red die (N719), black die (N749), etc. are applicable as the dyes.

Thus, the working electrode including the porous semiconductor layer 12 on which the dyes are adsorbed.

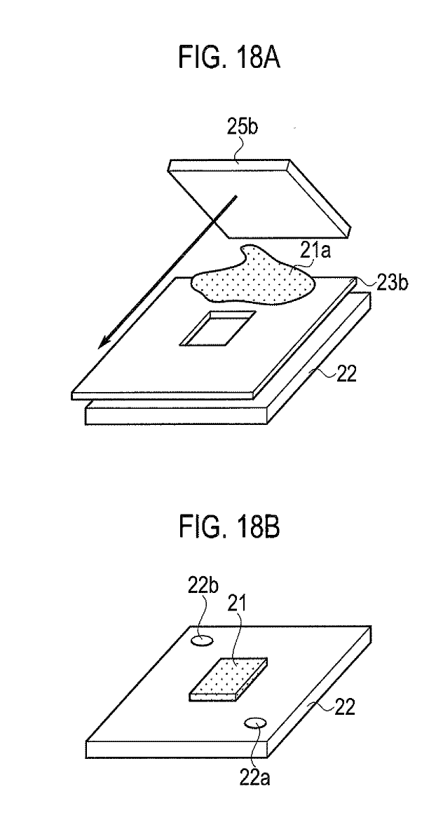

Next, with reference to FIGS. 18A-18B, an example of forms the catalyst layer 21 with the screen printing will be explained.

As shown in FIG. 18A, a mask member 23b having an aperture corresponding to the catalyst layer to be formed is aligned to set on the first substrate 22 after forming the first electrode 18. The thickness of the mask member 23b may be selected in accordance with a target thickness of the catalyst layer to be formed.

Subsequently, a paste including platinum precursor or a paste 21a including the activated carbon and the fine particles of the metal oxide (e.g., TiO₂, ZnO, SnO₂, WO₃, etc.) is coated on the mask member 23b, and a squeegee 25b is shifted to an arrow direction so that the paste 21a is filled up in the aperture of the mask member 23b.

Next, as shown in FIG. 18B, after removing the mask member 23b therefrom, the catalyst layer 21 is formed by annealing the paste layer at a predetermined temperature.

At this point, although the ITO fine particles may become a higher resistance film after the air annealing, the low-resistivity of the film may be achieved by performing the anneal processing under the N₂ atmosphere again.

Although FIGS. 17A-17D and 18A-18B show the process for obtaining the porous semiconductor layer 12 and the catalyst layer 21 by coating with the screen printing and by the subsequent annealing, various kinds of the porous films can also be obtained in the similar process by changing the paste to be coated.

Moreover, an injection hole 22a for the electrolysis solution 14 and an air vent hole 22b for air venting at the time of the injecting are punched by using the drill etc. in the two opposed corners in the first substrate 22. If a vacuum injection method from the edge face is adopted in the case of injection of the electrolysis solution described below, it is not necessary to form the injection hole 22a for the electrolysis solution 14 and the air vent hole 22b for air venting at the time of the injecting.

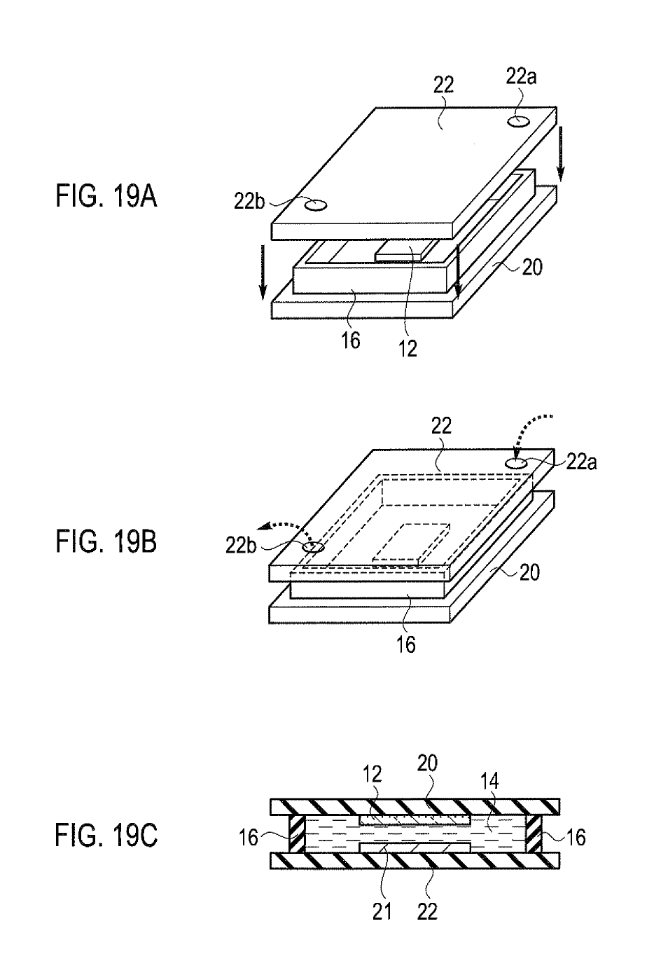

With reference to FIGS. 19A-19C, a method of assembling the dye-sensitized photovoltaic device 200 etc. will be explained.

As shown in FIG. 19A, a sealant 16 composed of an ultraviolet curing resin etc. is coated along an edge part of the second substrate 20 in which the porous semiconductor layer 12 is formed in the process shown in FIGS. 17A-17D, and the first substrate 22 in which the catalyst layer 21 is formed in the process shown in FIGS. 18A-18B is positioned to be overlaid.

Subsequently, it irradiates the sealant 16 with ultraviolet light etc. from the first substrate 22 side so as to be hardened, and the second substrate 20 and the first substrate 22 are mutually bonded via the sealant 16.

Subsequently, as shown in FIG. 19B, the electrolysis solution 14 is injected into the injection hole 22a formed in the first substrate 22. In this case, since the internal air is removed from the air vent hole 22b, the electrolysis solution 14 can be injected smoothly.

Subsequently, the injection hole 22a and the air vent hole 22b are sealed (not shown) by bonding of the glass plate, restoration of a resin, etc., so that there may be no leakage of the electrolysis solution 14.

Accordingly, the configuration of the dye-sensitized photovoltaic device 200 shown in FIG. 19C is assembled.

### (State of ITO Fine Particles Contained Film)

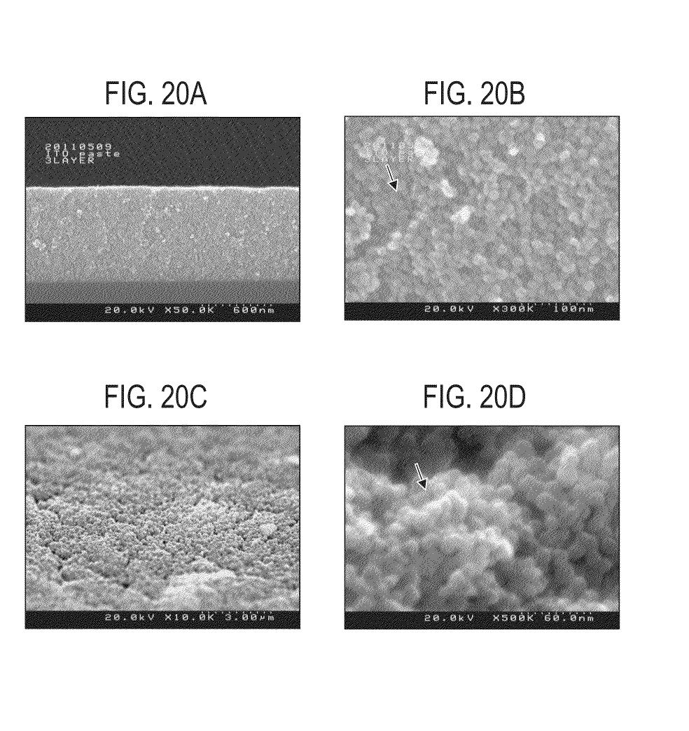

FIGS. 20A-20D show the state of the ITO fine particles contained film after the air annealing and the anneal process under the N₂ atmosphere.

FIG. 20A is a photographic view showing a cross-sectional shape of the ITO nanoparticle film. FIG. 20B is a photographic view in which the ITO nanoparticles shown in FIG. 20A are enlarged partially. FIG. 20C is a photographic view showing a surface shape of the ITO nanoparticle film. FIG. 20D is a photographic view in which the ITO nanoparticles shown in FIG. 20C are enlarged partially. Portions shown by the arrows in FIGS. 20B and 20D are the ITO nanoparticles.

As shown in FIGS. 20A and 20B, the ITO nanoparticles re in the state of being densely contacted with each other, and thereby high electrical conductivity is obtained.

Moreover, as shown in FIGS. 20C and 20D, there is surface roughness on the ITO nanoparticle film, and the effect that the incident light to the film is diffused without reflecting, different from the sputtered ITO film, can be obtained. Moreover, since the occupied area of the platinum or the activated carbon formed on the upper part thereof increases remarkable, the catalytic activity can be improved.

(Power Generation Characteristics of Dye-Sensitized Photovoltaic Device according to First Embodiment)

Cell evaluation is performed for the substrate obtained at the above processes as a counter electrode substrate of the dye-sensitized photovoltaic device 200.

Consequently, there can be obtained the photovoltaic power generation characteristics under the low-illumination light source as 2001× and under the high-illumination light source as 10001× substantially equivalent to characteristics fabricated with the ITO film substrate formed by sputtering.

In the present experiment, the ITO film substrate formed by sputtering is adopted as each the working electrode side.

Moreover, a substrate on which ultra-thin TiO2 is formed by coating Titanium (IV) Isopropoxide solution on the nanoparticle surface, and a substrate on which the ultra-thin TiO₂ is not formed were used as a working electrode side substrate of the dye-sensitized photovoltaic device, respectively, for the transparent conductive film substrate with the ITO nanoparticle film which becomes lower resistance. Consequently, the substrate having the block layer in which the ultra-thin TiO₂ was formed can improve remarkably the open circuit voltage in the photovoltaic power generation characteristics.

In the present experiment, the ITO film substrate formed by sputtering is adopted as each the counter electrode side.

It is estimated that the above-mentioned effect is the result of controlling the reverse current from the ITO nanoparticles to the electrolysis solution due to the effect of the block layer.

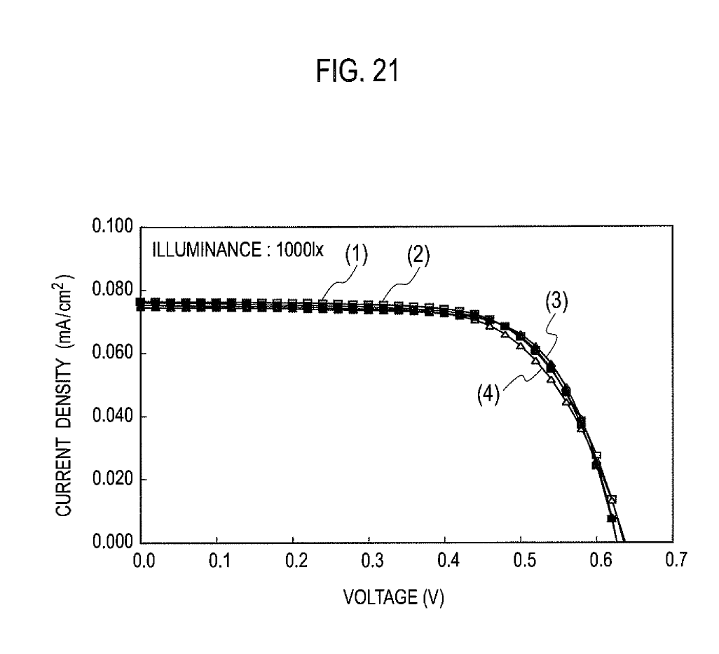

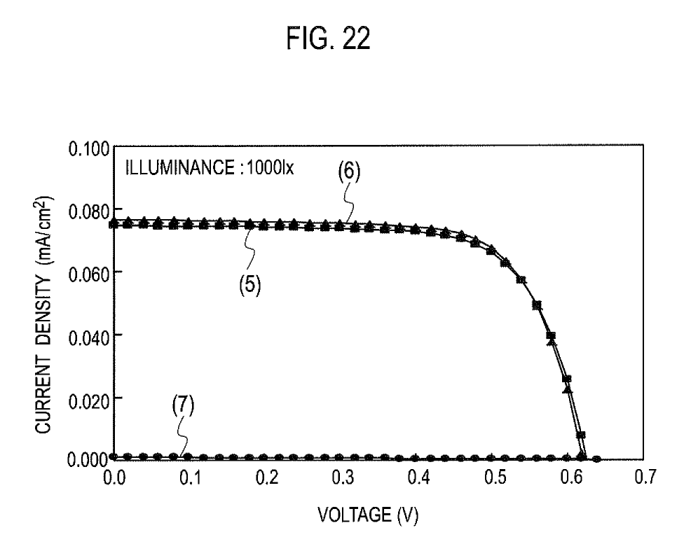

FIGS. 21 and 22 show graphic charts showing photovoltaic power generation characteristics (relationship between the current density and the voltage).

FIG. 21 is a graphic chart showing photovoltaic power generation characteristics (relationship between the current density and the voltage) with regard to the ITO film according to the comparative example, and photovoltaic power generation characteristics (relationship between the current density and the voltage) with regard to the ITO film applied to the dye-sensitized photovoltaic device according to the first embodiment. FIG. 22 is a graphic chart showing photovoltaic power generation characteristics (relationship between the current density and the voltage) with regard to the ITO film according to the comparative example, and photovoltaic power generation characteristics (relationship between the current density and the voltage) with regard to the ITO film applied to the dye-sensitized photovoltaic device according to the first embodiment.

The dye-sensitized type photovoltaic device was fabricated in comparing the ITO nanoparticle film formed under the conditions which become a lower resistive film with the ITO film formed by using conventional sputtering. Only the transparent conductive film at the side of the counter electrode was compared.

In FIG. 21, the conditions (1) are conditions where the N₂ annealing (anneal process) is performed with the ITO sputtering substrate. The conditions (2) are conditions where the N₂ annealing (anneal process) is performed with the ITO fine particles coating substrate. The conditions (3) are conditions where the N₂ annealing (anneal process) is not performed with the ITO sputtering substrate. The conditions (4) are conditions where the N₂ annealing (anneal process) is not performed with the ITO fine particles coating substrate.

The details of the result of the experiment on the conditions (1) are that the short-circuit current density (mA/cm²) is 0.076, the open circuit voltage (V) is 0.63, the filling factor is 0.69, and the maximum output density (mw/cm²) is 0.033.

The details of the result of the experiment on the conditions (2) are that the short-circuit current density (mA/cm²) is 0.075, the open circuit voltage (V) is 0.63, the filling factor is 0.71, and the maximum output density (mw/cm²) is 0.033.

The details of the result of the experiment on the conditions (3) are that the short-circuit current density (mA/cm²) is 0.076, the open circuit voltage (V) is 0.64, the filling factor is 0.67, and the maximum output density (mw/cm²) is 0.032.

The details of the result of the experiment on the conditions (4) are that the short-circuit current density (mA/cm²) is 0.075, the open circuit voltage (V) is 0.64, the filling factor is 0.66, and the maximum output density (mw/cm²) is 0.032.

In the present experiment, the photovoltaic power generation characteristics which do not almost have the difference are confirmed from lower illumination to higher illumination under 2001× and 10001×. However, since a tendency of only filling factor (FF) to reduce is confirmed as it becomes higher illumination when the ITO nanoparticle film becomes a higher resistance film, low resistive coating technology will be available. Only the transparent conductive film at the side of the counter electrode was compared in the present experiment.

In FIG. 22, the conditions (5) are the case where the air annealing is implemented respectively after forming the ITO fine particles and forming the catalyst layer, and then the N₂ annealing is finally implemented. The conditions (6) are the case where the air annealing is implemented only once after forming the ITO particle layer and forming the catalyst layer, and then the N₂ annealing is finally implemented. The conditions (7) are the cases where only N₂ annealing is once implemented after forming the ITO particle layer and forming the catalyst layer.

In this experiment, the anneal process under the N₂ atmosphere is added, since the low-resistivity of the transparent conductive film is important when the photovoltaic device using the ITO nanoparticles 300 is fabricated. Only the transparent conductive film at the side of the counter electrode was compared.

When performing the anneal process under the N₂ atmosphere, it is necessary to perform the air annealing before the anneal process. Such a process produces an effect of removing a film at the particle interface to reduce aggregation between the ITO nanoparticles, and produces an action as a conducting film.

The details of the result of the experiment on the conditions (5) are that the short-circuit current density (mA/cm²) is 0.075, the open circuit voltage (V) is 0.63, the filling factor is 0.71, and the maximum output density (mw/cm²) is 0.033.

The details of the result of the experiment on the conditions (6) are that the short-circuit current density (mA/cm²) is 0.076, the open circuit voltage (V) is 0.62, the filling factor is 0.71, and the maximum output density (mw/cm²) is 0.034.

The details of the result of the experiment on the conditions (7) are that the short-circuit current density (mA/cm²) is 0.001, the open circuit voltage (V) is 0.64, the filling factor is 0.25, and the maximum output density (mw/cm²) is 0.0001.

As the graphic chart curve of the conditions (7) shown in FIG. 22 indicated, it is proved that the photovoltaic power generation characteristics are reduced remarkable only by the anneal process under the N₂ atmosphere.

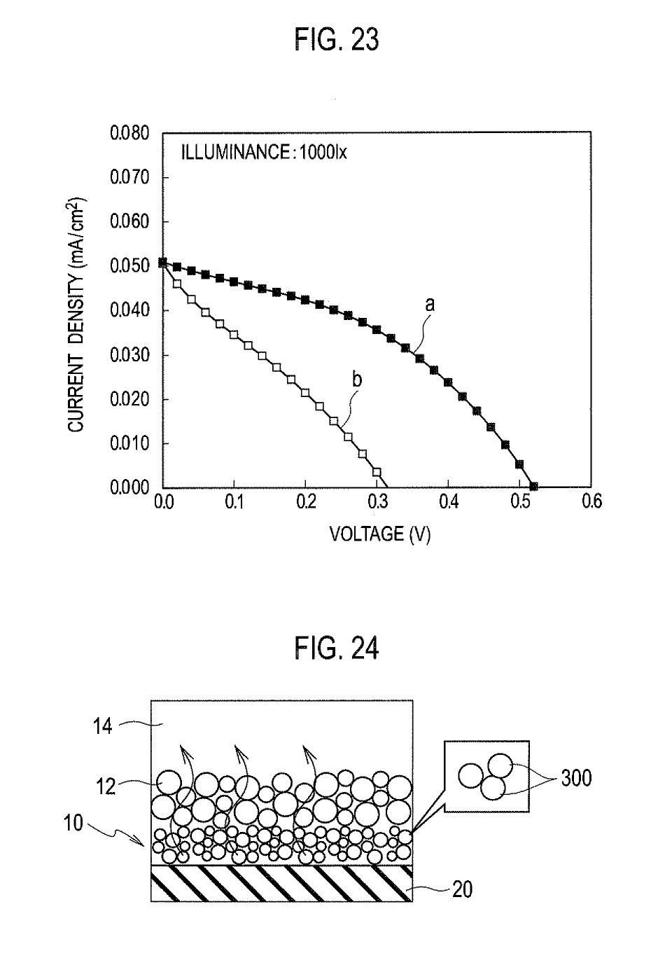

FIG. 23 shows a graphic chart showing the photovoltaic power generation characteristics (relationship between the current density and the voltage) in the case where the block layer 301 is formed on the ITO nanoparticles 300 (curve a (with barrier layer)), and in the case where the block layer 301 is not forming thereon (curve b (without barrier layer)).

In this case, as shown in FIG. 24, when not forming the block layer on the ITO nanoparticles 300, the reverse current from the ITO nanoparticles 300 to the electrolysis solution 14 causes the reduction of the open circuit voltage. Therefore, if the block layer is not formed on the ITO nanoparticles 300 as shown in the curve b of FIG. 23, the reduction of the power generation characteristics is observed under 10001×.

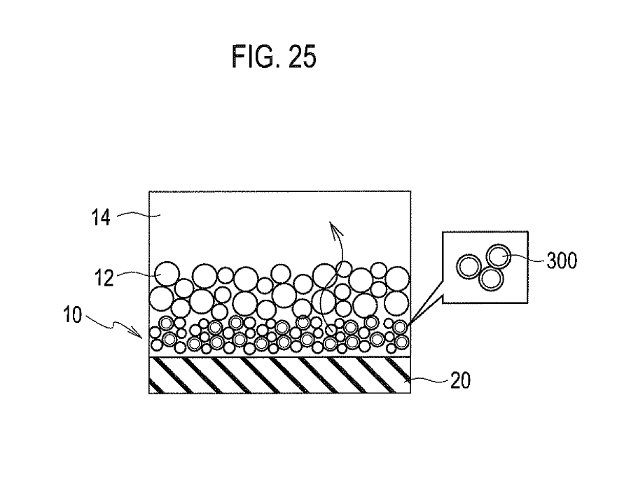

On the other hand, if the block layer 301 is formed on the ITO nanoparticles 300 as shown in FIG. 25, since the block layer 301 controls the reverse current, thereby improving the reduction of the open circuit voltage. Therefore, if the block layer 301 is formed on the ITO nanoparticles 300, it is observed that the power generation characteristics are improved under 10001× as shown in the curve a of FIG. 23, as compared with the curve b.

### Second Embodiment

### Fabrication Method of a Plurality of Dye-Sensitized Photovoltaic Devices

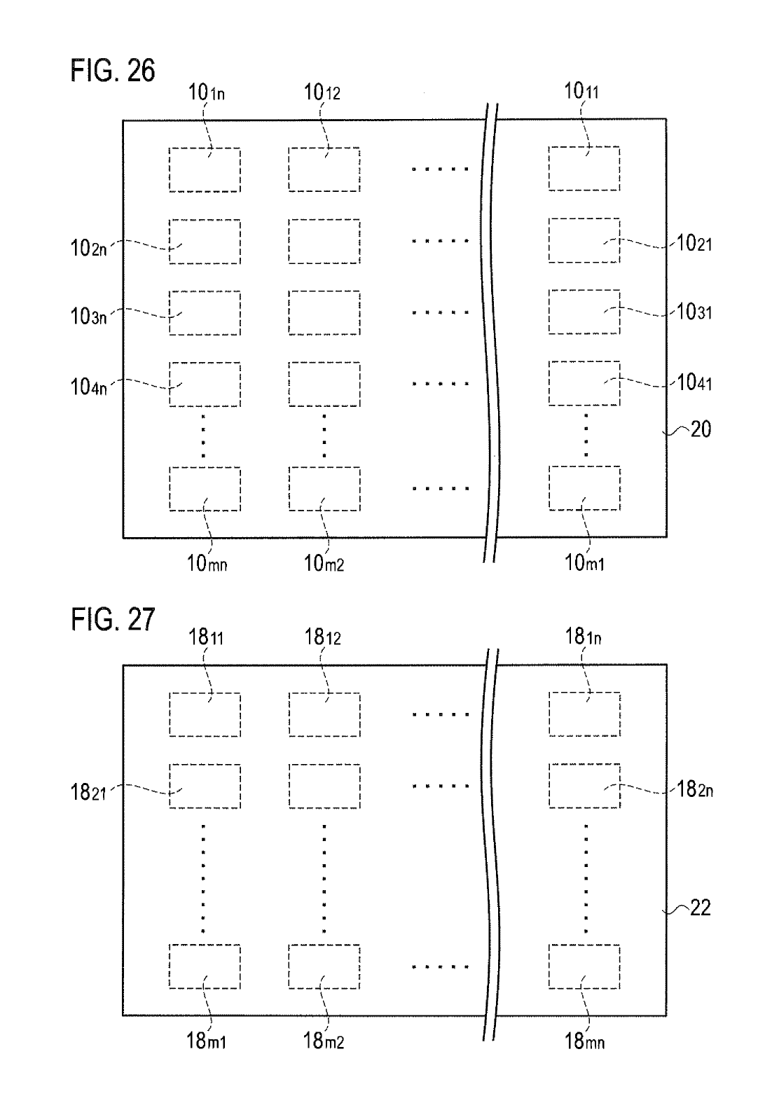

Next, with reference to FIGS. 26-31, there will be explained another fabrication method of a dye-sensitized photovoltaic device 200 according to a second embodiment.

The fabrication method of the dye-sensitized photovoltaic device according to the second embodiment is a fabrication method of a plurality of the dye-sensitized photovoltaic devices 200 by making a plurality of cells (e.g., m×n cells: where m and n are respectively integers), and then separating them.

As shown in FIG. 26, total m×n transparent electrodes (where m and n are respectively integers) 10₁₁-10ₘₙ are formed respectively inserting a predetermined space on the second substrate 20 composed of a glass substrate or a flexible plastic substrate.

As explained in the first embodiment, the ITO fine particles contained film coated by the screen printing is subjected to the air annealing and the anneal process under the N₂ atmosphere, and thereby the transparent electrodes 10₁₁-10ₘₙ are formed. If the ITO fine particles 300 on which the block layer 301 is formed are used, the power generation characteristics will be improved.

Although the porous semiconductor layer 12 (not shown) is formed on each transparent electrode 10₁₁-10ₘₙ.

The porous semiconductor layer 12 can be formed by apply the screen printing etc. shown in the fabrication method of the dye-sensitized photovoltaic device 200 according to the first embodiment. Moreover, dyes are adsorbed to each porous semiconductor layer 12.

Moreover, as shown in FIG. 27, total m×n first electrodes (where m and n are respectively integers) 18₁₁-18ₘₙ are formed respectively inserting a predetermined space on the first substrate 22 composed of a glass substrate etc.

As explained in the first embodiment, the ITO fine particles contained film coated by the screen printing is subjected to the air annealing and the anneal process under the N₂ atmosphere, and thereby the first electrodes 18₁₁-18ₘₙ are formed.

Although the catalyst layer 21 (not shown) is formed on each first electrode 18₁₁-18ₘₙ.

The catalyst layer 21 can be formed by apply the screen printing etc. shown in the fabrication method of the dye-sensitized photovoltaic device 200 according to the first embodiment.

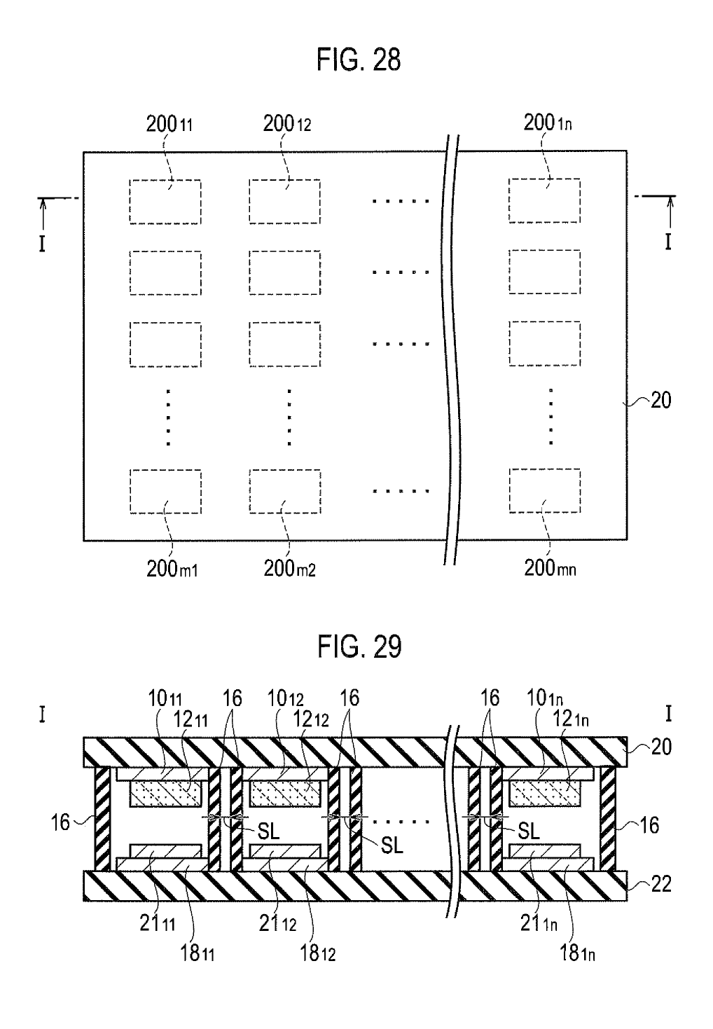

Then, as shown in FIG. 28, the sealant 16 composed of an ultraviolet curing resin etc. for every cell is coated on the first substrate 22, and the second substrate 20 is aligned with the high accuracy to be overlapped with the first substrate 22. Then, the sealant 16 is hardened by irradiation of ultraviolet light etc., and the configuration in which the first substrate 22 and the second substrate 20 are bonded via the sealant 16 is formed.

FIG. 29 is a schematic cross-sectional structure diagram showing the dye-sensitized photovoltaic device composed as mentioned above taken in the line I-I of FIG. 28.

As shown in FIG. 29, there is apart where only the substrate remains between the sealants 16, but the part will be used as a scribe line described later to separate it into each cell by the break of the blow etc.

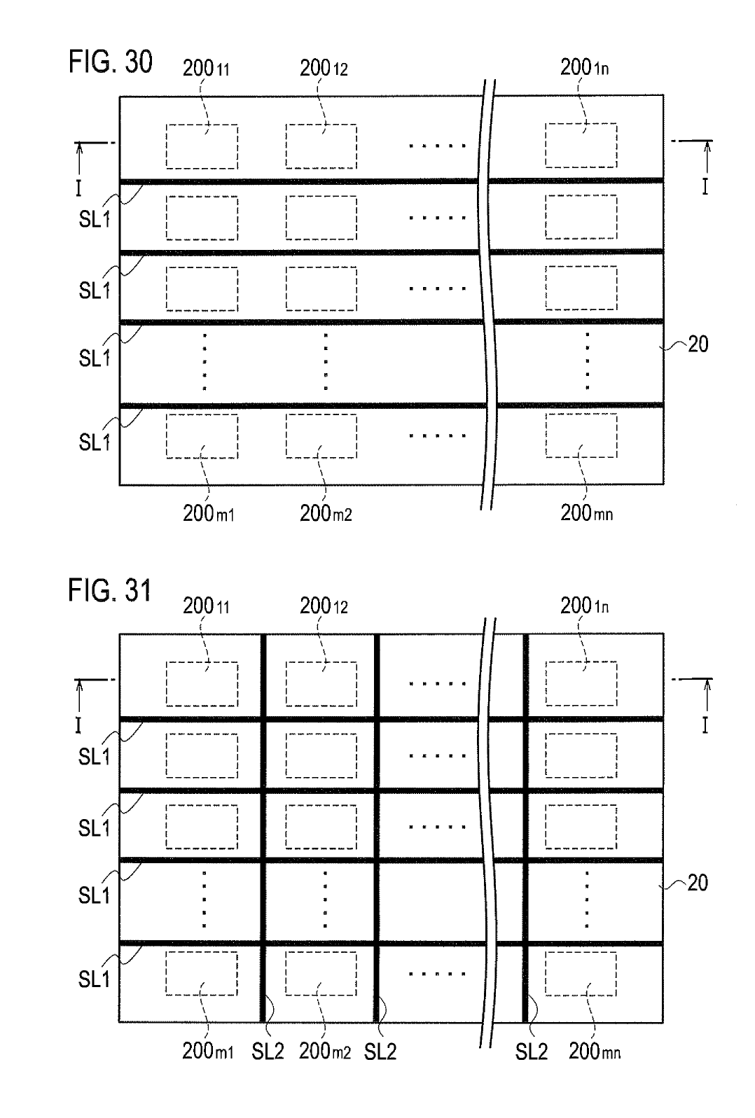

Subsequently, in the condition that total m×n dye-sensitized photovoltaic devices are bonded, as shown in FIG. 29, horizontal scribe lines SL1 are formed as shown in FIG. 30.

More specifically, each scribe line SL1 is formed by aligning a scribing wheel in a scribing device with high accuracy to a position on which the sealant 16 is formed.

Subsequently, as shown in FIG. 31, longitudinal scribe lines SL2 are formed.

Then, if the blow is dealt along with the scribe lines SL1 and the scribe lines SL2, the cells will be broken due to a cleavage of glass materials along with the scribe lines SL1 and the scribe lines SL2 to be separated into each cell.

After separating into each cell, the electrolysis solution is injected therein and sealed by bonding of glass plates, or by filling resins, etc. (not shown), and the dye-sensitized photovoltaic device is completed with treating so that the electrolysis solution may not begin to leak.

According to the fabrication method of the dye-sensitized photovoltaic device according to the second embodiment, there can be achieved lower manufacturing cost of the dye-sensitized photovoltaic device 200 which improved the power generation characteristics.

### Other Embodiments

While the present invention is described in accordance with the aforementioned embodiment and its modified example, it should be understood that the description and drawings that configure part of this disclosure are not intended to limit the present invention. This disclosure makes clear a variety of alternative embodiments, working examples, and operational techniques for those skilled in the art.

Such being the case, the present invention covers a variety of embodiments, whether described or not.

### INDUSTRIAL APPLICABILITY

The dye-sensitized photovoltaic device as in the present invention can generate electricity with the incident light from low-illumination light sources as not only the sunlight but indoor light. Therefore, the dye-sensitized photovoltaic device is applicable to various systems (e.g., auxiliary power for various electronic equipment (e.g., portable transmitter devices and game machine devices), and driving power sources of wireless sensor network modules) by applying as an electronic power supply.

What is claimed is:

1. A dye-sensitized photovoltaic device comprising:
a first substrate;
a first electrode disposed on the first substrate;
a catalyst layer formed on the first electrode, the catalyst layer having a catalytic activity for a redox electrolyte;
an electrolysis solution configured to be contacted with the catalyst layer and to dissolve the redox electrolyte in a solvent;
a porous semiconductor layer configured to be contacted with the electrolysis solution and to include semiconductor fine particles and dye molecules;
a second electrode disposed on the porous semiconductor layer;
a second substrate disposed on the second electrode; and
a sealant disposed between the first substrate and the second substrate, and sealing the electrolysis solution, wherein
the first electrode and the second electrode are composed of an annealed layer of an ITO fine particles contained film coated on the first substrate and the second substrate.

2. The dye-sensitized photovoltaic device according to claim 1, wherein the ITO fine particles contained film is composed by being laminated up to a thickness of not more than 1 μm.

3. The dye-sensitized photovoltaic device according to claim 1, wherein a block layer comprised of one of TiO₂ and Nb₂O₅ is formed on a surface of the ITO fine particles included in the annealed layer formed on the second substrate.

4. The dye-sensitized photovoltaic device according to claim 3, wherein a particle diameter of the ITO fine particles is 10-20 nm, and a thickness of the block layer is not more than 10 nm.

5. The dye-sensitized photovoltaic device according to claim 1, wherein the ITO fine particles contained film formed on the first substrate is formed by coating a paste including the ITO fine particles on the first substrate.

6. The dye-sensitized photovoltaic device according to claim 3, wherein the ITO fine particles contained film including the ITO fine particles on which the block layer is formed on the second substrate is formed by coating a solution, after coating the paste including the ITO fine particles on the second substrate.

7. The dye-sensitized photovoltaic device according to claim 1, wherein the first substrate and the second substrate are composed of respectively one selected from the group consisting of a soda-lime glass, an inorganic alkaline glass, and a silica glass.

8. The dye-sensitized photovoltaic device according to claim 3, wherein the block layer is formed by coating a precursor solution of one of TiO₂ and Nb₂O₅ on a surface of the ITO fine particles by using a spin coat method or a dip method.

9. The dye-sensitized photovoltaic device according to claim 1, wherein the porous semiconductor layer is formed by annealing after coating the paste including semiconductor fine particles on the second substrate.

10. The dye-sensitized photovoltaic device according to claim 1, wherein the catalyst layer is formed by annealing after coating one of a paste including platinum precursor and a paste including an activated carbon and fine particles of metal oxide of TiO₂, ZnO, SnO₂, WO₃, on the first electrode.

11. A fabrication method of a dye-sensitized photovoltaic device comprising:
forming an ITO fine particles contained film on a first substrate;
performing air annealing of the ITO fine particles contained film on the first substrate at a temperature not more than the melting point of the first substrate;
adding an anneal process to the ITO fine particles contained film on the first substrate under N₂ atmosphere at a temperature not more than the melting point of the first substrate to form a first electrode, after the air annealing;
forming a conductive thin film as a catalyst layer on the first electrode;
adding an anneal process to the ITO fine particles contained film under the N₂ atmosphere again in the formation of the electrical conductivity thin film, in order to achieve low-resistivity of the ITO fine particles having high resistance;
forming an ITO fine particles contained film including the ITO fine particles on the second substrate;
performing air annealing of the ITO fine particles contained film on the second substrate at a temperature not more than the melting point of the second substrate;
forming a block layer;
adding an anneal process to the ITO fine particles contained film on the second substrate at a temperature not more than the melting point of the first substrate under N₂ atmosphere to form a second electrode;
forming a porous semiconductor layer including semiconductor fine particles on the second electrode;
adding an anneal process to the ITO fine particles contained film under the N₂ atmosphere again in the formation of the porous semiconductor layer, in order to achieve low-resistivity of the ITO fine particles having high resistance;
impregnating the porous semiconductor layer with a dye solution to adsorbing dye molecules;
bonding a counter electrode substrate in which the first electrode and the catalyst layer are formed on the first substrate, and a working electrode substrate in which the second electrode and the porous semiconductor layer to which the dye molecules are adsorbed are formed, via a sealant; and
injecting an electrolysis solution between the counter electrode substrate and the working electrode substrate.

12. The fabrication method according to claim 11, wherein the step of forming the ITO fine particles contained film on the first substrate is a step of coating a paste including ITO fine particles on the first substrate.

13. The fabrication method according to claim 11, wherein the step of forming the ITO fine particles contained film including the ITO fine particles on which the block layer is formed on the second substrate is a step of forming the block layer by coating a solution, after coating a paste including ITO fine particles on the second substrate.

14. The fabrication method according to claim 11, wherein the temperature not more than the melting point is 450-550 degrees C. if the first substrate and the second substrate are composed of a soda-lime glass, and the anneal is performed at equal to or greater than 550 degrees C. if the first substrate and the second substrate are composed of an inorganic alkaline glass and a silica glass.

15. The fabrication method according to claim 11, wherein the conditions under the N₂ atmosphere are conditions of flowing N₂ of more than 1 sccm in the condition that oxygen concentration is controlled.

16. The fabrication method according to claim 11, wherein the block layer is formed by coating a precursor solution of one of TiO₂ and Nb₂O₅ on a surface of the ITO fine particles by using a spin coat method or a dip method.

17. A fabrication method of a dye-sensitized photovoltaic device comprising:
forming an ITO fine particles contained film on a first substrate;
performing air annealing of the ITO fine particles contained film on the first substrate at a temperature not more than the melting point of the first substrate;
adding an anneal process to the ITO fine particles contained film on the first substrate under N₂ atmosphere at a temperature not more than the melting point of the first substrate to form a first electrode, after the air annealing;
forming a conductive thin film as a catalyst layer on the first electrode;
adding an anneal process to the ITO fine particles contained film under the N₂ atmosphere again in the formation of the electrical conductivity thin film, in order to achieve low-resistivity of the ITO fine particles having high resistance;
forming an ITO fine particles contained film including the ITO fine particles on the second substrate;
performing air annealing of the ITO fine particles contained film on the second substrate at a temperature not more than the melting point of the second substrate;
forming a block layer;
adding an anneal process to the ITO fine particles contained film on the second substrate at a temperature not more than the melting point of the first substrate under N₂ atmosphere to form a second electrode;
forming a porous semiconductor layer including semiconductor fine particles on the second electrode;
adding an anneal process to the ITO fine particles contained film under the N₂ atmosphere again in the formation of the porous semiconductor layer, in order to achieve low-resistivity of the ITO fine particles having high resistance;
impregnating the porous semiconductor layer with a dye solution to adsorbing dye molecules;
bonding a counter electrode substrate in which a plurality of the first electrodes and a plurality of catalyst layers are formed on the first substrate and, a working electrode substrate in which a plurality of the second electrodes and a plurality of the porous semiconductor layers to which the dye molecules are adsorbed are formed on the second substrate via a sealant, so that the cells respectively to be the dye-sensitized photovoltaic devices are divided in each other;
forming scribe lines for separating for every cell respectively to be the dye-sensitized photovoltaic devices on the first substrate or the second substrate;
breaking the cells to be separated along the scribe lines; and
implanting an electrolysis solution into each cell of the separated dye-sensitized photovoltaic device.
